(19) United States
(12) Patent Application Publication
(10) Pub. No.: US 2011/0290547 A1
(43) Pub. Date: Dec. 1, 2011

(54) ELECTRODE STRUCTURE OF MULTIPLE DIELECTRIC ISLAND LAYER AND MANUFACTURING METHOD THEREOF

(75) Inventors: Wen-Lung CHEN, Chu-Nan (TW); Wen-Lung LU, Chu-Nan (TW); Yu-Chun TSENG, Chu-Nan (TW)

(73) Assignee: CHIMEI INNOLUX CORPORATION, Chu-Nan (TW)

(21) Appl. No.: 13/098,210

(22) Filed: Apr. 29, 2011

(30) Foreign Application Priority Data
May 28, 2010 (TW) 099117310

(51) Int. Cl. H05K 1/11; H05K 3/06

(52) U.S. Cl. 174/261; 216/13

(57) ABSTRACT

An electrode structure of multiple dielectric island layer and manufacturing method thereof are described. The electrode structure includes a substrate, an electrode bridge structure, a dielectric layer and a conducting pattern. The dielectric layer is formed on the substrate and the electrode bridge structure and has a plurality of dielectric island patterns. The dielectric island patterns cover a portion of the electrode bridge structure for forming a plurality of bridge patterns of the electrode bridge structure wherein the dielectric island patterns are alternately arranged with the bridge patterns. The conducting pattern has a first electrode, a second electrode, a third electrode and a fourth electrode. The first electrode is electrically connected to the second electrode. The third and fourth electrodes cover the bridge patterns of the electrode bridge structure for reducing the contact resistance between the third and fourth electrodes by the electrode bridge structure.

### CROSS REFERENCE TO RELATED APPLICATIONS

This Application claims priority of Taiwan Patent Application No. 99117310, filed on May 28, 2010, the entirety of which is incorporated by reference herein.

### BACKGROUND OF THE INVENTION

1. Field of the Invention

The present invention relates to an electrode structure and method thereof, and more particularly to an electrode structure of multiple dielectric island layer and manufacturing method thereof, wherein the electrode structure is applicable to a capacitive touch panel.

2. Description of the Related Art

Please refer to FIG. 1. FIG. 1 is a schematic view of a conventional electrode structure 100 of a capacitive touch panel. The electrode structure 100 includes a substrate 102, a metal conducting wire 104, a dielectric layer 106, a transparent electrode layer 108 and a passivation layer 110. The metal conducting wire 104, the dielectric layer 106 and the transparent electrode layer 108 are sequentially formed wherein the transparent electrode layer 108 has a left-side electrode 108a, a right-side electrode 108b and a conducting wire 108c, and the two end portions of the metal conducting wire 104 are electrically connected to the left-side electrode 108a and the right-side electrode 108b, respectively.

However, the step coverage of the transparent electrode layer 108 is poor near the step edge between the dielectric layer 106 and the metal conducting wire 104, as shown in FIG. 1. The step height formed by the dielectric layer 106 and the metal conducting wire 104 causes the non-uniform coverage conformation of the transparent electrode layer 108. In this situation, the defects 105 are easily formed at the two end portions of the metal conducting wire 104 so that the electrical contact between the transparent electrode layer 108 and the metal conducting wire 104 is poor or disconnected, which degrades the signal transmission between the left-side electrode 108a and the right-side electrode 108b. As shown in FIG. 1, a defect 105, i.e. open loop status, is between the left-side of the metal conducting wire 104 and the left-side electrode 108a. The contact interface between the right-side of the metal conducting wire 104 and the transparent electrode layer 108 is deficient or defective, which results in the increased contact resistance between the transparent electrode layer 108 and the metal conducting wire 104.

Additionally, when the uncovered area of the metal conducting wire 104 by the dielectric layer 106 is too small, i.e. length “L” is shrunk, the metal conducting wire 104 cannot be completely covered with the transparent electrode layer 108 so that the transparent electrode layer 108 is disconnected from the metal conducting wire 104. In this case, the signal transmission between the left-side electrode 108a and the right-side electrode 108b fails. When the uncovered area of the metal conducting wire 104 by the dielectric layer 106 is increased, i.e. length “L” is enlarged, the bright spots are formed on the capacitive touch panel so that the display quality of capacitive touch panel is degraded. Consequently, there is a need to improve the conventional electrode structure of capacitive touch panel.

### BRIEF SUMMARY OF THE INVENTION

The objective of the present invention is to provide an electrode structure of multiple dielectric island layer and manufacturing method thereof for reducing the contact resistance between the conducting pattern and the electrode bridge structure by a plurality of bridge patterns to allow the electrode bridge structure to stably transmit the sensing signal.

According to the above objectives, the present invention provides an electrode structure of multiple dielectric island layer and manufacturing method thereof. The electrode structure includes a substrate, an electrode bridge structure, a dielectric layer, a conducting pattern and passivation layer. The electrode structure is electrically connected to the control circuit via the electrode wires wherein the control circuit processes the sensing signal transmitted from the electrode structure.

The electrode bridge structure is formed on the substrate. For example, the electrode bridge structure is composed of alloy material. The dielectric layer is formed on the electrode bridge structure and the substrate and has a plurality of dielectric island patterns thereof, wherein each of the dielectric island patterns covers a portion of the electrode bridge structure for forming a plurality of exposed bridge patterns of the electrode bridge structure, and each of the dielectric island patterns is alternately arranged with each of the bridge patterns along a predetermined direction.

The conducting pattern is formed on the substrate and has a first electrode, a second electrode, a third electrode and a fourth electrode, wherein the first electrode is electrically connected to the second electrode. The third electrode and the fourth electrode cover the bridge patterns of the electrode bridge structure to allow the electrode bridge structure to electrically connect to the third electrode and the fourth electrode. The electrode bridge structure is electrically insulated from the first electrode and the second electrode respectively by the dielectric layer. Thus, the third electrode and the fourth electrode are electrically insulated from the first electrode and the second electrode by the dielectric layer.

A method of manufacturing an electrode structure includes the following steps of:

(1) forming an electrode bridge structure on a substrate;

(2) forming a dielectric layer on the electrode bridge structure and the substrate;

(3) etching the dielectric layer for forming a plurality of dielectric island patterns, wherein each of the dielectric island patterns covers a portion of the electrode bridge structure for forming a plurality of bridge patterns of the electrode bridge structure, and each of the dielectric island patterns is alternately arranged with each of the bridge patterns along a predetermined direction;

(4) forming a conducting pattern on the substrate;

(5) etching the conducting layer for forming a conducting pattern having a first electrode, a second electrode, a third electrode and a fourth electrode, wherein the first electrode is electrically connected to the second electrode, the third electrode and the fourth electrode cover the bridge patterns of the electrode bridge structure to allow the electrode bridge structure to electrically connect to the third electrode and the fourth electrode, the electrode bridge structure is electrically insulated from the first electrode and the second electrode respectively by the dielectric layer, and the third electrode and the fourth electrode are electrically insulated from the first electrode and the second electrode by the dielectric layer; and

(6) forming a passivation layer on the conducting pattern and the dielectric layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view of a conventional electrode structure of a capacitive touch panel;

FIG. 2 is a schematic layout view of the electrode structure according to one embodiment of the present invention;

FIGS. 3A-3F are schematic cross-sectional process views of manufacturing the electrode structure shown in FIG. 2 along cross-sectional line A-A′ according to one embodiment of the present invention; and

FIG. 4 is a schematic block diagram of the electronic device having a capacitive touch panel according to one embodiment of the present invention.

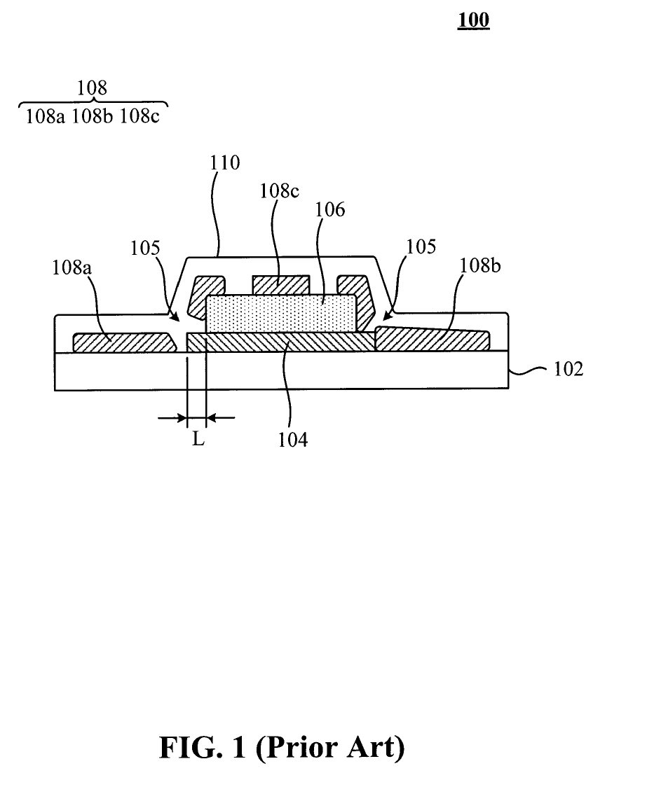

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

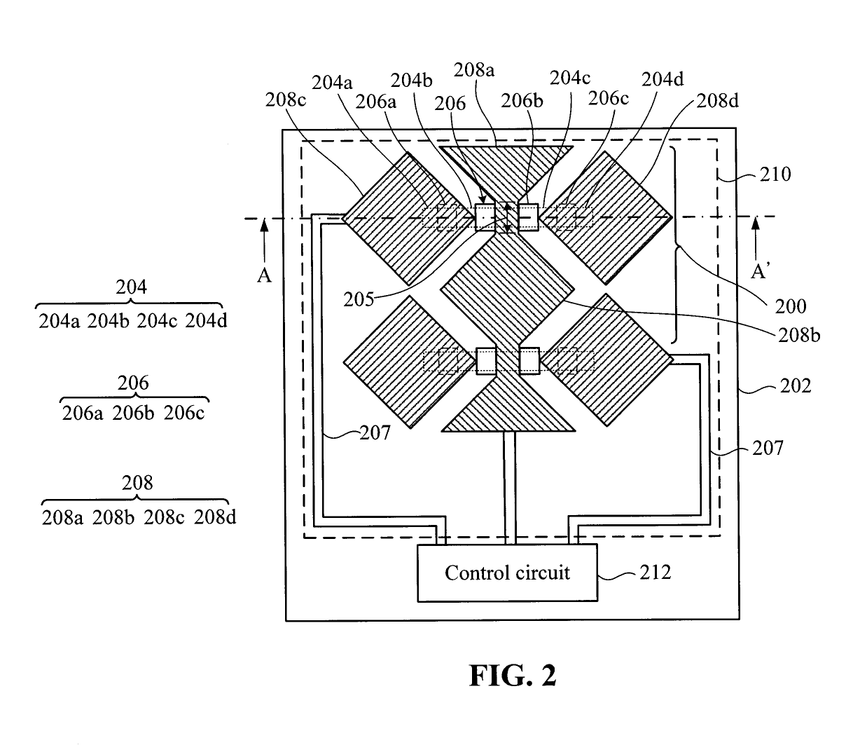

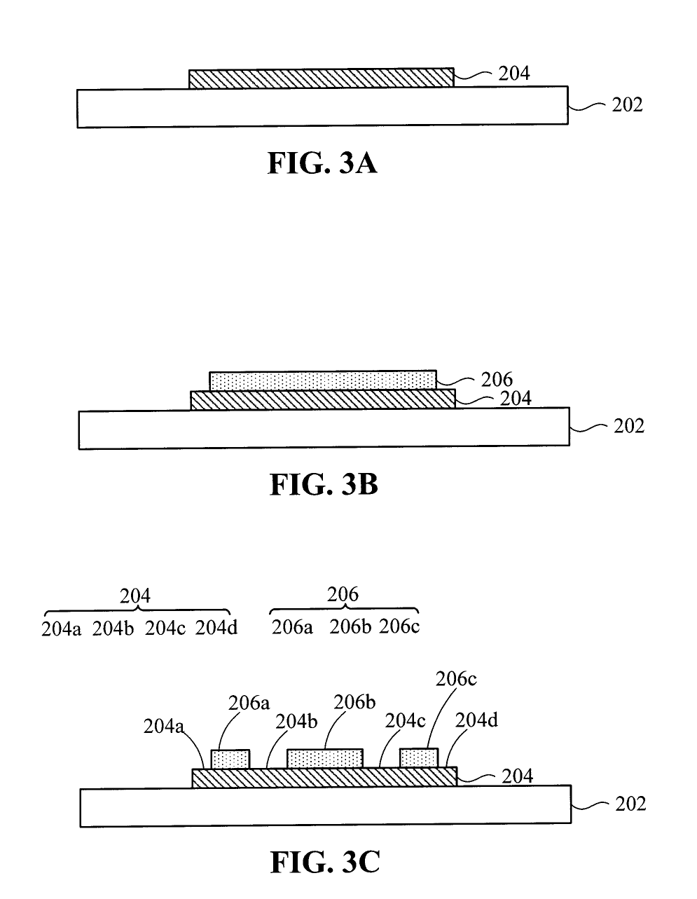

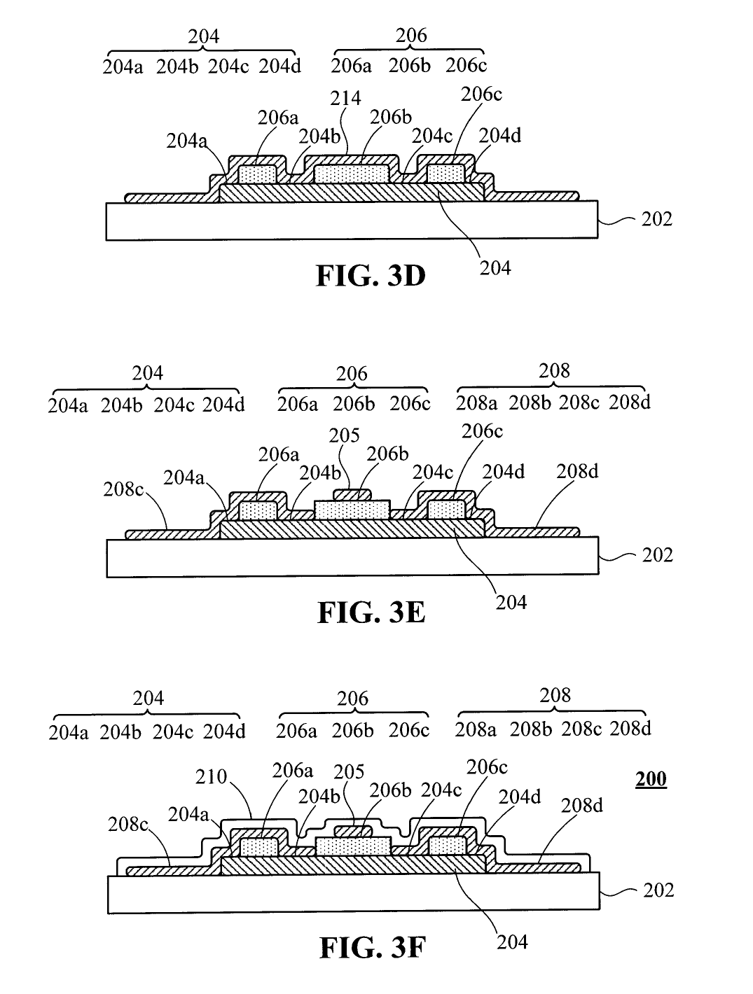

FIG. 2 is a schematic layout view of the electrode structure 200 according to one embodiment of the present invention. The electrode structure 200 (as shown in FIG. 3F) is applicable to a capacitive touch panel. The electrode structure 200 includes a substrate 202, an electrode bridge structure 204, a dielectric layer 206, a conducting pattern 208 and passivation layer 210. The electrode structure 200 is electrically connected to the control circuit 212 via the electrode wires 207, wherein the control circuit 212 processes the sensing signal transmitted from the electrode structure 200. The electrode wires 207 and the conducting pattern 208 are disposed in different regions of the substrate 202. In this case, there are two electrode structures 200 disposed on the top and bottom portions of the substrate but more than two electrode structures 200 may be disposed in a form of array arrangement in the present invention.

The electrode bridge structure 204 is formed on the substrate 202. For example, the electrode bridge structure 204 is composed of alloy material, e.g. metal conducting wire, which is selected from the group consisting of palladium (Pd), platinum (Pt), aurum (Au), argentums (Ag) and aluminum (Al). In one preferred embodiment, the electrode bridge structure 204 has a thickness range from 0.2 μm to 10 μm. Alternatively, the electrode bridge structure 204 has an arbitrary thickness range which can be completely covered with the dielectric layer 206.

The dielectric layer 206 is formed on the electrode bridge structure 204 and the substrate 202 and has a plurality of dielectric island patterns 206a, 206b, 206c thereof, wherein each of the dielectric island patterns 206a, 206b, 206c covers a portion of the electrode bridge structure 204 for forming a plurality of exposed bridge patterns 204a, 204b, 204c, 204d of the electrode bridge structure 204, and each of the dielectric island patterns 206a, 206b, 206c is alternately arranged with each of the bridge patterns 204a, 204b, 204c, 204d along a predetermined direction. That is, the bridge patterns 204a, 204b, 204c, 204d are formed along cross-sectional line A-A′ in FIG. 2 by covering the electrode bridge structure 204 in a discontinuity form. In other words, a dielectric island pattern 206a, 206b, or 206c is disposed between two bridge patterns 204a, 204b, 204c, 204d. The thickness of the dielectric layer 206 has a range from 0.1 μm to 5 μm. An interval distance of each of the dielectric island patterns 206a, 206b, 206c has a range from 0.3 μm to 40 μm.

The conducting pattern 208 is formed on the substrate 202 and has a first electrode 208a, a second electrode 208b, a third electrode 208c and a fourth electrode 208d wherein the first electrode 208a is electrically connected to the second electrode 208b. The third electrode 208c and the fourth electrode 208d cover the bridge patterns 204a, 204b, 204c, 204d of the electrode bridge structure 204 to allow the electrode bridge structure 204 to electrically connect to the third electrode 208c and the fourth electrode 208d. The electrode bridge structure 204 is electrically insulated from the first electrode 208a and the second electrode 208b respectively by the dielectric layer 206. Thus, the third electrode 208c and the fourth electrode 208d are electrically insulated from the first electrode 208a and the second electrode 208b by the dielectric layer 206. In one embodiment, the first electrode 208a is electrically connected to the second electrode 208b by the conducting wire 205. Additionally, the dielectric layer 206 is disposed in the adjacent region among the first electrode 208a, the second electrode 208b, the third electrode 208c and the fourth electrode 208d. The thickness of the conducting pattern 208 has a range from 0.01 μm to 0.3 μm, preferably from 0.03 μm to 0.05 μm.

Specifically, the electrode structure 200 in the present invention utilizes the dielectric layer 206 to form the dielectric island patterns 206a, 206b, 206c and exposes the bridge patterns 204a, 204b, 204c, 204d of the electrode bridge structure 204. When the conducting pattern 208 is formed on the substrate 202, the third electrode 208c and the fourth electrode 208d electrically contact the bridge patterns (204a, 204b, 204c, 204d) for lengthening the conducting trace path between the third electrode 208c, the fourth electrode 208d and the electrode bridge structure 204 to reduce the contact resistance between the conducting pattern 208 and the electrode bridge structure 204. Therefore, the electrode bridge structure 204 is capable of stably transmitting the sensing signal. In the electrode structure 200, besides the exposed bridge patterns 204a, 204d of electrode bridge structure 204 are not covered with the dielectric layer 206, the exposed bridge patterns 204b, 204c are also not covered with the dielectric layer 206. Thus, because the conducting contact area between the third electrode 208c and the electrode bridge pattern 204, the fourth electrode 208d and the electrode bridge structure 204 is increased, the exposed bridge patterns 204b, 204c of electrode bridge structure 204 can transmit the sensing signal all the time even if the third electrode 208c, the fourth electrode 208d have defects in the bridge patterns 204a, 204d.

Please refer to FIG. 2 and FIGS. 3A-3F. FIGS. 3A-3F are schematic cross-sectional process views of manufacturing the electrode structure 200 (as shown in FIG. 3F) shown in FIG. 2 along cross-sectional line A-A′ according to one embodiment of the present invention. A method of manufacturing an electrode structure which is suitable for a capacitive touch panel includes the following steps.

In FIG. 3A, an electrode bridge structure 204 is formed on a substrate 202. For example, a dry etching or wet etching manner is employed to form the electrode bridge structure 204. The electrode bridge structure 204 is composed of alloy material, e.g. metal conducting wire. The substrate 202 is selected from one group consisting of glass, plastic and transparent material. The plastic material is selected from the group consisting of polyester resin, polyacrylate resin, polyolefin resin, polyimide resin, polycarbonate resin and polyurethane resin. For example, the polyolefin resin is polyethylene (PE) or polypropylene (PP), the polyester resin is polyethylene terephthalate (PET), and the polyacrylate resin is polymethylmethacrylate (PMMA).

In FIG. 3B, a dielectric layer 206 is formed on the electrode bridge structure 204 and the substrate 202. The thickness of the dielectric layer 206 has a range from 0.1 μm to 5 μm.

In FIG. 3C, the dielectric layer 206 is etched for forming a plurality of dielectric island patterns 206a, 206b, 206c wherein each of the dielectric island patterns 206a, 206b, 206c covers a portion of the electrode bridge structure 204 for forming a plurality of bridge patterns 204a, 204b, 204c, 204d of the electrode bridge structure 204. Each of the dielectric island patterns 206a, 206b, 206c is alternately arranged with each of the bridge patterns 204a, 204b, 204c, 204d along a predetermined direction. That is, the bridge patterns 204a, 204b, 204c, 204d are formed along cross-sectional line A-A′ in FIG. 2 by covering the electrode bridge structure 204 in a discontinuity form. In other words, each of the dielectric island pattern 206a, 206b, or 206c is disposed between two bridge patterns 204a, 204b, 204c, 204d. An interval distance of each of the dielectric island patterns 206a, 206b, 206c has a range from 0.3 μm to 40 μm. The material of dielectric layer is selected from one group consisting of silicon oxide, silicon nitride (Si3N4), low dielectric constant (e.g. polymer having low dielectric constant smaller than ten) and transparent inorganic material. In one embodiment, the screen-printing technique, Asahi Kasei Photosensitive Resin (APR) coating technique and/or spray printing technique is utilized to from the dielectric layer 206.

In FIG. 3D, a conducting layer 214 is formed on the substrate 202 to cover the bridge patterns 204a, 204b, 204c, 204d and the dielectric island patterns 206a, 206b, 206c. In one embodiment, the sputtering method and/or the physical vapor deposition (PVD) method are utilized to form the conducting layer 214 and the material of conducting layer 214 is indium tin oxide (ITO).

In FIG. 3E, the conducting layer 214 is etched for forming a conducting pattern 208 and a conducting wire 205, wherein the conducting pattern 208 has a first electrode 208a (as shown in FIG. 2), a second electrode 208b (as shown in FIG. 2), a third electrode 208c and a fourth electrode 208d. The first electrode 208a is electrically connected to the second electrode 208b by the conducting wire 205. The third electrode 208c and the fourth electrode 208d cover the bridge patterns 204a, 204b, 204c, 204d of the electrode bridge structure 204 to allow the electrode bridge structure 204 to electrically connect to the third electrode 208c and the fourth electrode 208d. The electrode bridge structure 204 is electrically insulated from the first electrode 208a and the second electrode 208b respectively by the dielectric layer 206. The third electrode 208c and the fourth electrode 208d are further electrically insulated from the first electrode 208a and the second electrode 208b by the dielectric layer 206. For example, a dry etching or wet etching manner is employed to form the conducting pattern 208. The thickness of the conducting pattern 208 has a range from 0.01 μm to 0.3 μm, preferably from 0.03 μm to 0.05 μm.

In FIG. 3F, a passivation layer 210 is formed on the conducting pattern 208 and the dielectric layer 206. For example, the material of passivation layer 210 is silicon oxide or inorganic material and the thickness thereof is from 0.1 μm to 5 μm. In one embodiment, the screen-printing technique, Asahi Kasei Photosensitive Resin (APR) coating technique and/or spray printing technique is utilized to form the passivation layer 210.

According to the above-mentioned descriptions, the electrode structure 200 in the present invention employs the dielectric layer 206 to form the dielectric island patterns 206a, 206b, 206c and exposes the bridge patterns 204a, 204b, 204c, 204d of the electrode bridge structure 204. The third electrode 208c and the fourth electrode 208d electrically contact the bridge patterns 204a, 204b, 204c, 204d for lengthening the conducting trace path between the third electrode 208c, the fourth electrode 208d and the electrode bridge structure 204 to reduce the contact resistance between the conducting pattern 208 and the electrode bridge structure 204. Therefore, the electrode bridge structure 204 is capable of stably transmitting the sensing signal. In the electrode structure 200, besides the bridge patterns 204a, 204d of electrode bridge structure 204 are exposed, the bridge patterns 204b, 204c are also exposed. Thus, because the conducting contact area between the third electrode 208c and the electrode bridge structure 204, the fourth electrode 208d and the electrode bridge structure 204 is increased, the electrode bridge structure 204 can accurately transmit the sensing signal all the time.

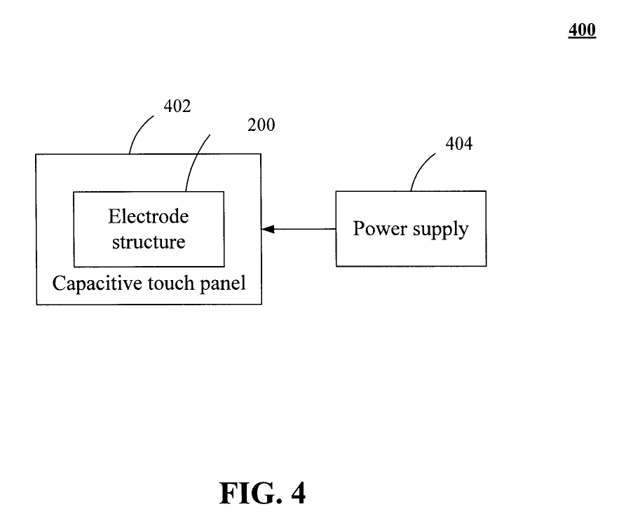

Please refer to FIG. 4. FIG. 4 is a schematic block diagram of the electronic device 400 having a capacitive touch panel 402 according to one embodiment of the present invention. The electronic device 400 includes an electrode structure 200, a capacitive touch panel 402 and a power supply 404. The electrode structure 200 is used for the capacitive touch panel 402 and the capacitive touch panel 402 is disposed in the electronic device 400. The power supply 404 is electrically connected to the capacitive touch panel 402 for supplying power to the capacitive touch panel 402. The electronic device 400 is selected from one group consisting of a mobile phone, a digital camera, a personal digital assistant (PDA), a notebook computer, a desktop computer, a television set, a global positioning system (GPS), an automobile display, a flight display, and a portable digital versatile disk (DVD).

According to the aforementioned descriptions, the present invention provides an electrode structure of multiple dielectric island layer and manufacturing method thereof for reducing the contact resistance between the conducting pattern and the electrode bridge structure by a plurality of bridge patterns to allow the electrode bridge structure to stably transmit the sensing signal.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrode structure, comprising:
a substrate;
an electrode bridge structure formed on the substrate;
a dielectric layer formed on the electrode bridge structure and the substrate and having a plurality of dielectric island patterns thereof, wherein each of the dielectric island patterns covers a portion of the electrode bridge structure for forming a plurality of bridge patterns of the electrode bridge structure, and each of the dielectric island patterns is alternately arranged with each of the bridge patterns along a predetermined direction; and
a conducting layer formed on the substrate and having a first electrode, a second electrode, a third electrode and a fourth electrode, wherein the first electrode is electrically connected to the second electrode, the third electrode and the fourth electrode cover the bridge patterns of the electrode bridge structure to allow the electrode bridge structure to electrically connect to the third electrode and the fourth electrode, and the electrode bridge structure is electrically insulated from the first electrode and the second electrode respectively by the dielectric layer.

2. The electrode structure of claim 1, wherein a thickness of the dielectric layer has a range from 0.1 μm to 5 μm.

3. The electrode structure of claim 1, wherein an interval distance of each of the dielectric island patterns has a range from 0.3 μm to 40 μm.

4. The electrode structure of claim 1, wherein the electrode bridge structure is alloy material.

5. The electrode structure of claim 1, wherein a thickness of the conducting pattern has a range from 0.03 μm to 0.05 μm.

6. A method of manufacturing an electrode structure which is suitable for a capacitive touch panel, the method comprising the steps of:
forming an electrode bridge structure on a substrate;
forming a dielectric layer on the electrode bridge structure and the substrate;
etching the dielectric layer for forming a plurality of dielectric island patterns, wherein each of the dielectric island patterns covers a portion of the electrode bridge structure for forming a plurality of bridge patterns of the electrode bridge structure and is alternately arranged with each of the bridge patterns along a predetermined direction;
forming a conducting layer on the substrate; and
etching the conducting layer for forming a conducting pattern having a first electrode, a second electrode, a third electrode and a fourth electrode, wherein the first electrode is electrically connected to the second electrode, the third electrode and the fourth electrode covers the bridge patterns of the electrode bridge structure to allow the electrode bridge structure to electrically connect to the third electrode and the fourth electrode, the electrode bridge structure is electrically insulated from the first electrode and the second electrode respectively by the dielectric layer, and the third electrode and the fourth electrode are electrically insulated from the first electrode and the second electrode by the dielectric layer.

7. The method of claim 6, wherein a thickness of the dielectric layer has a range from 0.1 μm to 5 μm.

8. The method of claim 6, wherein an interval distance of each of the dielectric island patterns has a range from 0.3 μm to 40 μm.

9. The method of claim 6, wherein a thickness of the conducting pattern has a range from 0.03 μm to 0.05 μm.

10. The method of claim 6, after the step of etching the conducting layer for forming the conducting pattern, further comprising a step of forming a passivation layer on the conducting pattern and the dielectric layer.
